(19) United States
(12) Patent Application Publication
(10) Pub. No.: US 2006/0133155 A1
(43) Pub. Date: Jun. 22, 2006

(54) Nonvolatile semiconductor memory device and a method of erasing data thereof

(75) Inventors: Norihiro Fujita, Yokohama-shi (JP); Hiroshi Nakamura, Fujisawa-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/293,376

(22) Filed: Dec. 5, 2005

(30) Foreign Application Priority Data
Dec. 8, 2004 (JP) 2004-354943

(51) Int. Cl. G11C 16/04

(52) U.S. Cl. 365/185.29

(57) ABSTRACT

A nonvolatile semiconductor memory device comprises memory cell array constituted of a plurality of memory blocks which electrically rewritable memory cells are arranged, before erasing data of all of said memory cells in the selected memory block in a plurality of said memory blocks, preprogram is performed to shift all threshold voltages of all of said memory cells in said selected memory blocks to positive.

### CROSS-REFERENCES TO RELATED APPLICATIONS

This application is based upon and claims the benefit of priority from the prior Japanese Patent Applications No. 2004-354943, filed on Dec. 8, 2004, the entire contents of which are incorporated herein by reference.

### BACKGROUND OF THE INVENTION

1. Field of the Invention

The present invention relates to an electrically rewritable nonvolatile semiconductor memory device. Among nonvolatile semiconductor memories, it especially relates to nonvolatile semiconductor memories of NAND cell type, NOR cell type, DINOR cell type and AND cell type EEPROM and others.

2. Description of Related Art

The EEPROM which can perform electric rewriting has been known as one of the semiconductor memory devices. Especially, the NAND cell type EEPROM which a plurality of memory cell are connected in series to constitute a NAND cell block attracts attention because higher integration is possible compared with other memories. A technology relating to data erasing of the NAND cell type EEPROM is described in Japanese Laid Open Patent Publication 2000-348492.

Here, referring to FIG. 1, threshold voltage distribution of the memory cell before and after the data erasing operation is explained. FIG. 1 shows threshold voltage distribution before the erasing operation (a) (a dotted line) the threshold voltage distribution after the erasing operation (b) (a solid line).

As mentioned above, the data erasing operation is performed collectively by per block in the NAND cell type EEPROM. However, since the memory cells before erasing data are intermingled with data of “0” or “1” (whose threshold voltages are positive or negative), the threshold voltage distribution after erasing data will spread widely as is shown in FIG. 1(b). Thereby, in the case of successive writing of the data, variation in writing in each memory cell occurs, and variation of the time to complete writing of each memory cell occurs, and as a result, time for writing gets longer.

### BRIEF SUMMARY OF THE INVENTION

According to an aspect of the present invention, there is provided a nonvolatile semiconductor memory device comprising memory cell array constituted of a plurality of memory blocks which electrically rewritable memory cells are arranged, and before erasing data of all of said memory cells in the memory block selected from said plurality of memory blocks, threshold voltages of all of said memory cells in said selected memory block are shifted to be positive.

According to an aspect of the present invention, there is provided a nonvolatile semiconductor memory device comprising memory cell array constituted of a plurality of memory blocks which electrically rewritable memory cells are arranged, and said plurality of the memory blocks are constituted of the first domain and the second domain respectively, when data of a specific memory cell of said memory cells in said second domain of the memory block selected from said plurality of memory blocks is the first value, writing or erasing of the data to said selected memory block is permitted, when the data of said specific memory cell is the second value, writing or erasing of the data to said selected memory block is prohibited, when writing or erasing of the data to said memory block is permitted, before erasing the data of all of said memory cells in said selected memory blocks, all threshold voltages of all of said memory cells in said first domain in said selected memory block are shifted to be positive.

According to a semiconductor memory device of an aspect of the present invention, “0” data is written per block before the data erasing operation, and threshold voltage distribution of the memory cells in the selected block is shifted to be positive. Then, by performing the data erasing operation successively, threshold voltage distribution after the erasing operation can be narrower. Therefore, variation of time to complete writing of each memory cell at the time of writing the data performed successively after the data erasing operation can be smaller.

According to a semiconductor memory device of an aspect of the present invention, before the data erasing operation, “0” data is written in to the memory cells except for the area where identification flags and others are memorized, and while preventing incorrect erasing of the identification flag, threshold voltage distribution after the data erasing operation can be narrower, and variation of time to complete writing of each memory cell at the time of writing the data performed successively after the data erasing operation can be smaller. In addition, defect in writing the data can be restrained.

### BRIEF DESCRIPTION OF THE DRAWINGS

The accompanying drawings, which are incorporated into and form a part of the specification, illustrate one or more embodiments of the present invention, together with the description, serve to explain the principals of the invention. The drawings are only for the purpose of illustrating one or more preferred embodiments of the invention and are not to be construed as limiting the invention. In the drawings:

FIG. 1 is a diagram showing threshold voltage distribution of a memory cell before and after an erasing operation of data in a NAND cell type nonvolatile semiconductor memory device.

FIG. 2 shows a flowchart of an erasing operation of a NAND cell type nonvolatile semiconductor memory device.

FIG. 3 shows a schematic configuration of one embodiment of a nonvolatile semiconductor memory device of the present invention.

FIG. 4 is a circuit diagram showing an example of configuration of the memory cell array of one embodiment of a nonvolatile semiconductor memory device of the present invention.

FIG. 5 is a diagram showing cross section cut along with a bit line BL of one NAND cell unit concerning one embodiment of a nonvolatile semiconductor memory device of the present invention.

FIG. 6 is a flowchart at the time of erasing data of one embodiment of a nonvolatile semiconductor memory device of the present invention.

FIG. 7 is a diagram showing threshold voltage distribution of memory cells in the selected block before and after erasing data in one embodiment of a nonvolatile semiconductor memory device of the present invention.

FIG. 8 is a circuit diagram showing an example of configuration of memory cell array in one embodiment of a nonvolatile semiconductor memory device of the present invention.

FIG. 9 is an image diagram of one block of array of memory cells in one embodiment of a nonvolatile semiconductor memory device of the present invention.

FIG. 10 is a flowchart of an erasing operation in one embodiment of a nonvolatile semiconductor memory of the present invention.

FIG. 11 is an image diagram of one block of array of memory cells in one embodiment of a nonvolatile semiconductor memory device of the present invention.

FIG. 12 is an image diagram when all memory cells in the first domain and the second domain are tentatively preprogrammed in one embodiment of a nonvolatile semiconductor memory device of the present invention.

FIG. 13 is an image diagram of one block of array of memory cells in one embodiment of a nonvolatile semiconductor memory device of the present invention.

### DETAILED DESCRIPTION OF THE INVENTION

In this embodiment, a NAND cell type nonvolatile semiconductor memory device is used as an example of a nonvolatile semiconductor memory device of the present invention.

A data writing operation and a data erasing operation of the NAND cell type EEPROM is as follows. The data writing operation is mainly performed in order from a memory cell in the position most distant from a bit line. Firstly, when the data writing operation is started, according to a writing data, 0V (“0” data writing) or a power supply voltage Vcc (“1” data writing) is given to a bit line, and Vcc is given to the select gate line at the selected bit line side. In this case, when the bit line is 0V, in the connected select NAND cell, a channel region in the NAND cell is fixed at 0V via a select gate transistor. When the bit line is Vcc, in the connected select NAND cell, the channel region in the NAND cell will be in a floating state, after being charged up to [Vcc−Vtsg] (provided that, Vtsg is a threshold voltage of the select gate transistor) via the select gate transistor.

Next, a control gate line of the select memory cell in the select NAND cell is set to Vpp (=about 20V: a high voltage for writing) from 0V, and the control gate line of the unselected memory cell in the select NAND cell is set to Vmg (=about 10V: a middle voltage) from 0V.

Here, when the bit line is 0V, in the connected select NAND cell, since the channel region in the NAND cell is fixed at 0V, large potential difference (=about 20V) occurs between a gate of the selected memory cell in the select NAND cell (=Vpp potential) and the channel region (=0V), and electron injection occurs from the channel region into a floating gate. Thereby, threshold voltage of the select memory cell is shifted to positive direction, and writing of “0” data is completed.

On the other hand, when the bit line is Vcc, in the connected select NAND cell, since the channel region in the NAND cell is in a floating state, along with voltage rise (from 0V to Vpp, Vmg) of the control gate line caused by the effect of capacity coupling between the control gate line in the select NAND cell and the channel region, while potential of the channel region maintains the floating state, [Vcc−Vtsg] potential is increased to Vmch (=about 8V). At this time, since potential difference between the gate of the select memory cell in the select NAND cell (=Vpp potential) and the channel region (=Vmch) is comparatively as small as about 12V, electron injection does not occur, and therefore threshold voltage of the select memory cell is not shifted but is maintained in the negative state, and the writing of “1” data is completed.

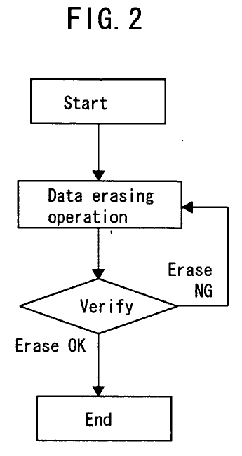

Next, the data erasing operation of the NAND cell type EEPROM is explained. A flowchart of the erasing operation of the NAND cell type EEPROM is shown in FIG. 2. Data erasing of the NAND cell type EEPROM is simultaneously performed to all memory cells in the selected NAND cell block. That is, all control gates in the selected NAND cell block are set to 0V, and a high voltage of about 20V is impressed to the bit line, a source line, a p type well (or a p type substrate), the control gate in the unselected NAND cell block and all select gates Thereby, in all memory cells in the select NAND cell block, electrons of a floating gate are discharged to the p type well (or the p type substrate), and threshold voltages of all of the memory cells in the selected block are shifted to negative direction. Thus, in the NAND cell type EEPROM, the data erasing operation will be performed per block collectively.

Next, as shown in FIG. 2, after the above-mentioned data erasing operation is performed, verification is conducted whether the data of all of the memory cells in the selected block are erased completely. When it is verified that the data of all memory cells in the selected block are erased completely, erasing of data is completed. On the other hand, when it is verified that a part of the data of all memory cells in the selected block are not erased, the above-mentioned data erasing operation is performed again. Accordingly, data erasing of the NAND cell type EEPROM is performed.

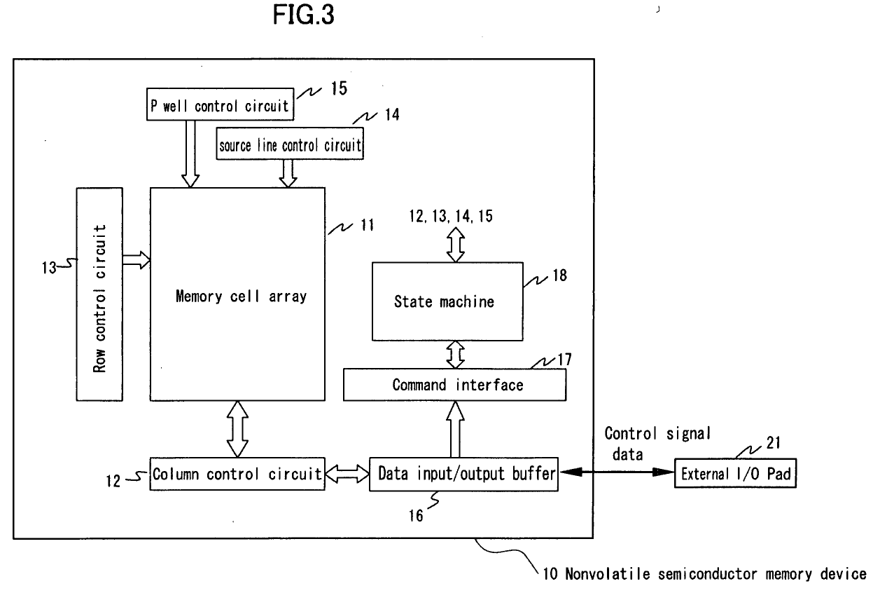

FIG. 3 is referred to. FIG. 3 shows a schematic configuration of a nonvolatile semiconductor memory device 10 concerning this embodiment. The nonvolatile semiconductor memory device 10 concerning this embodiment comprises a memory cell array 11, a column control circuit (a column decoder) 12, a row control circuit (a row decoder) 13, a source line control circuit 14, a P well control circuit 15, a data input and output buffer 16, a command interface 17 and a state machine 18. The nonvolatile semiconductor memory device 10 of the present invention concerning this embodiment performs sending and receiving of data and a control signal (command) with an external I/O pad 19.

In the nonvolatile semiconductor memory device 10 concerning this embodiment, data and a control signal are inputted into the command interface 17 and the column control circuit 12 through the data input and output buffer 16 from the external I/O pad 19. The state machine 18 controls the column control circuit 12, the row control circuit 13, the source line control circuit 14 and the P well control circuit 15 based on the control signal and the data. The state machine 18 outputs access information regarding memory cells of the memory cell array 11 to the column control circuit 12 and the row control circuit 13. The column control circuit 12 and the row control circuit 13 activate the memory cells based on the subject access information and the data, and reading, writing or erasing of the data is performed. The column control circuit 12 includes a sense amplifier and a data cache, and the sense amplifier connected to each bit line of the memory cell array 11 loads the data to a bit line and detects the potential of the bit line and holds it in the data cache. The data read from the memory cells by the sense amplifier controlled by the column control circuit 12 is outputted to the external I/O pad 19 through the data input and output buffer 16.

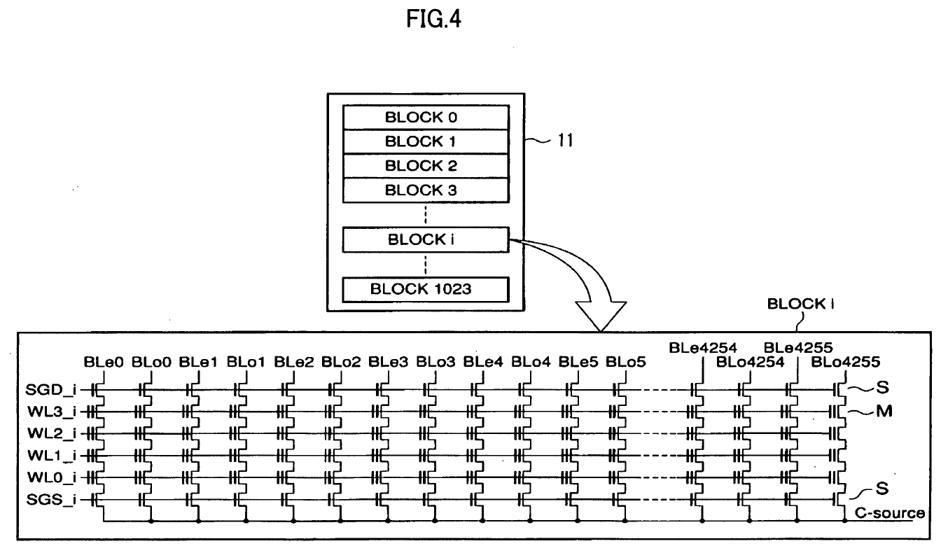

Next, FIG. 4 is referred to. FIG. 4 is a circuit diagram of an example of configuration of the memory cell array 11 in the nonvolatile semiconductor memory device 10 concerning this embodiment. In this embodiment, the memory cell array 11 is divided into a plurality of blocks BLOCK0 to BLOCK1023 (a total of 1024 units). Here, a “block” is the minimum unit for data erasing. In this embodiment, each block of BLOCK0 to BLOCK1023 is constituted of the NAND type memory units of 8512, as shown in the block BLOCKi representatively.

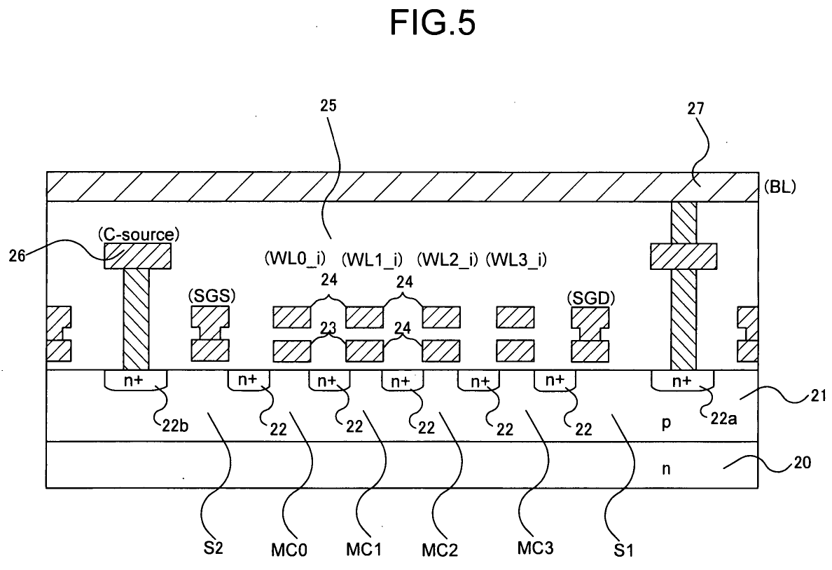

FIG. 5 shows a cross section cut along with a bit line BL of the NAND cell including one NAND memory unit. Memory cells MC0 to MC3 are formed on a p type well 21 formed over an n type silicon substrate or an n type well 20. The adjoining memory cells of MC0 to MC3 share source and drain diffusion layers 22, and the lamination structure of the floating gates 23 and the control gates 24 are formed. Patterning is performed on the control gates 24 traced over the word line WL common to a plurality of memory cells MC0 to MC3 in the orthogonal direction of this figure. A common source line (C-source) 26 within a block embedded to the inside of said interlayer insulating film 25 contacts with a source diffusion layer 22b of the selection gate transistor S2 at the side of the common source line (C-source). The bit line (BL) 27 formed over the interlayer insulating film 25 contacts with a drain diffusion layer 22a of the selection gate transistor S1 at the side of said bit line BL.

In this embodiment, each NAND type memory unit is configured by connecting four memory cells M in series, and one end is connected to the bit lines BL (BLe0 to BLe4255, BLo0 to BLo4255) via the select gate S connected to the select gate line SGD, and the other end is connected to the common source line C-source via the select gate S connected to the select gate line SGS. The control gate of each memory cell M is connected to the word lines WL (WL0_i to WL3_i). The even-numbered bit line BLe and the odd-numbered bit line BLo counted from 0 perform writing and read-out of data while mutually independent. Writing and read-out of data are simultaneously performed to 4256 units of memory cells connected to the even-numbered bit line BLe among 8512 units of the memory cells connected with one word line WL. The data of 1 bit which each memory cell memorizes will be 4256 units of the memory cells to constitute the unit of a page.

Similarly, another page is constituted of 4256 memory cells connected to the odd-numbered bit line BLo, and writing and read-out of data are simultaneously performed to the memory cells in a page. 4256 units of memory cells in 1 page will have a storage capacity of 532 bytes.

Although this embodiment includes the number of the blocks constituting a memory cell is set to 1024 and the NAND type memory unit composed of four memory cells which one block is 8512, it is not necessarily limited to this and the number of blocks, the number of memory cells and the number of memory units can be changed according to desired capacity.

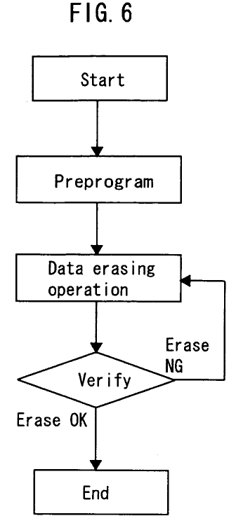

Next, FIG. 6 is referred to. FIG. 6 shows a flowchart at the time of erasing data of the nonvolatile semiconductor memory device 10 of the present invention concerning this embodiment. In the nonvolatile semiconductor memory device 10 of the present invention concerning this embodiment, when erasing data, an operation to write “0” data is performed per block over the selected block before performing the data erasing operation, and after threshold voltages of all of the memory cells in the selected block are shifted to the positive threshold voltages (“0” data), the data erasing operation will be carried out. Here, the writing operation of “0” data per block performed before this data erasing operation is called “preprogram”. The method mentioned above can be used for the voltage applied to the control gate, the bit line, the source line, the p type well (or the p type substrate) and others at the time of the data erasing operation.

After the data erasing operation is performed, verification is conducted whether the data of all memory cells in the selected block are erased completely. When it is verified that the data of all memory cells in the selected block are erased completely, erasing of the data is completed. On the other hand, when it is verified that a part of the data in all memory cells in the selected block are not erased, the data erasing operation is performed again. Accordingly, the data of the selected block is erased.

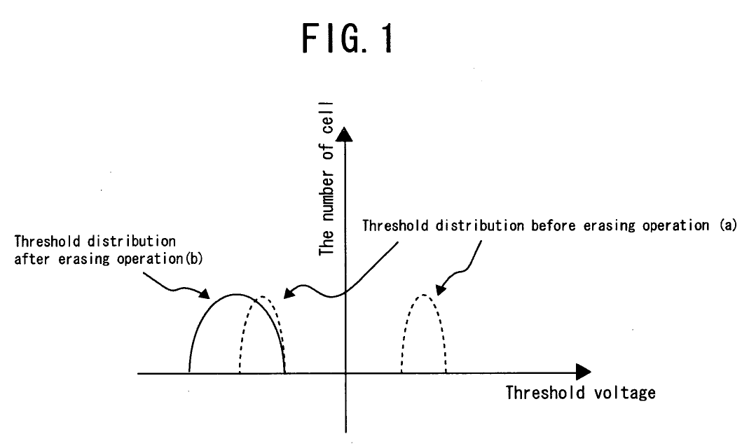

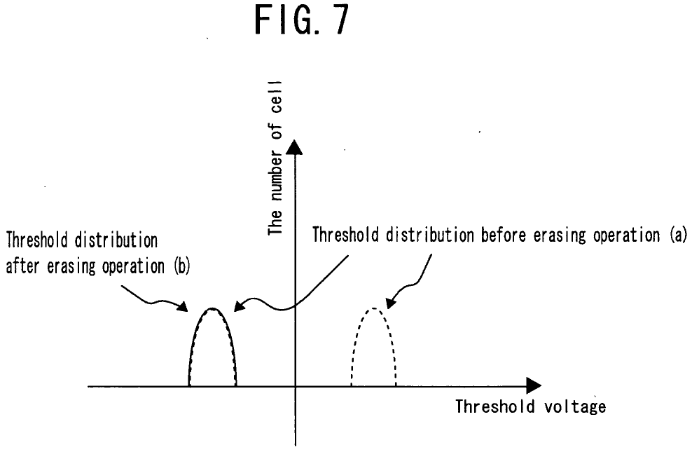

FIG. 7 shows threshold voltage distribution of the memory cells within the select block before and after performing data erasing in this embodiment. In FIG. 7, (a) shows the threshold voltage distribution before erasing data (a dotted line), and (b) shows the threshold voltage distribution after erasing data (a solid line). As shown in FIG. 7, by performing the data erasing in this embodiment, compared with the data erasing shown in FIG. 1, the threshold voltage distribution after the data erasing can be narrower. Therefore, variation of time to complete writing of each memory cell at the time of writing the data performed continuously after the data erasing operation can be smaller. In addition, defects in data writing can be restrained.

### EMBODIMENT 1

In this embodiment, another embodiment of a semiconductor memory device of the present invention is explained. The general configuration of the nonvolatile semiconductor memory device 10 of this embodiment is the same as the ones explained in the above-mentioned embodiment and FIG. 3.

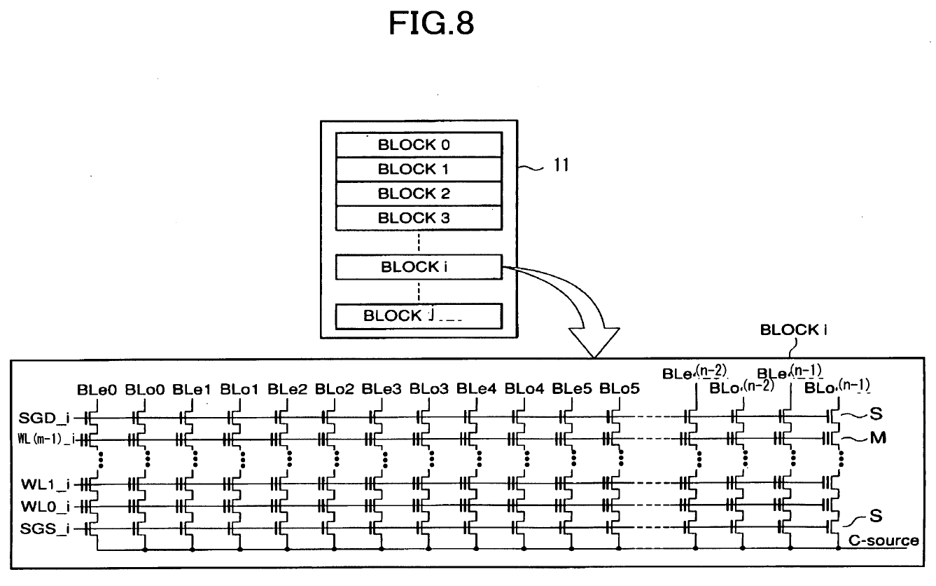

FIG. 8 is referred to. FIG. 8 shows a circuit diagram of an embodiment of configuration of the memory cell array 11 of the nonvolatile semiconductor memory device 10 concerning this embodiment. In this embodiment, the memory cell array 11 is divided into a plurality of blocks BLOCK0 to BLOCKj (a total of j units). In this embodiment, each block BLOCK0 to BLOCKj is constituted of 2n units of the NAND type memory unit, as the block BLOCKi shows representatively.

In this embodiment, each NAND type memory unit is configured to connect m units of the memory cells M in series, and one end is connected to the bit lines BL (BLo0 to BLe (n−1), BLo0 to BLo (n−1)) via the select gate S coupled to the select gate line SGD, and the other end is connected to the common source line C-source via the select gate S coupled to the select gate line SGS. The control gates of each memory cell M are connected with the word lines WL (WL0_i to WL(m−1)_i).

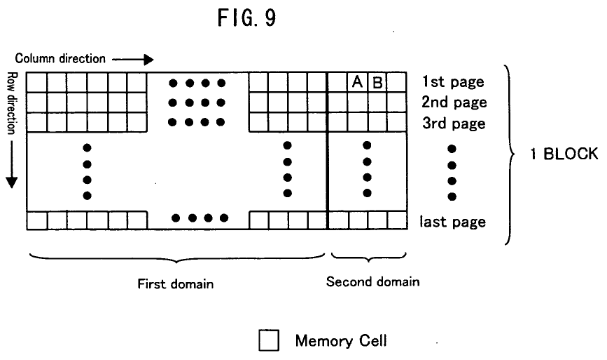

Here, FIG. 9 is referred to. FIG. 9 shows an image diagram of one block among j units of the memory blocks of the memory cell array 11 of this embodiment. In FIG. 9, one square shows one memory cell. In this embodiment, the number of the word line WL (WL0_i to WL(m−1)_i) is m, and since the even-bit lines and the odd-bit lines of the bit lines (BLo0 to BLe (n−1), BLo0 to BLo (n−1)) form a respective page, the number of pages in one block is 2m. In this embodiment, as shown in FIG. 9, a group of the memory cells for 4 bits in each page is defined as the second domain, and a group of the memory cells for (n−4) bit in each page is defined as the first domain. Therefore, in this embodiment, the first domain has storage capacity of 2m×(n−4)/8=(mn/4−1) byte, and the second domain has storage capacity of 2m×4/8=m bytes. The storage capacity of the first domain and the second domain is not limited to the number described in this embodiment. Although the memory block which the even-bit lines and the odd-bit lines constitute a respective page is explained in this embodiment, the nonvolatile semiconductor memory device concerning the present invention of this embodiment is not limited to this, and a nonvolatile semiconductor memory device having memory blocks of an ABL (All Bit Line) method which does not distinguish an even-bit line and an odd-bit line may be used. In this case, the number of word lines corresponds with the number of pages.

In this embodiment, the first domain and the second domain are used as a user area and a non-user area, respectively. The user area means a memory cell domain which can control writing, erasing and reading of the data by the command disclosed to a general user. The non-user area means a memory cell domain which can control writing, erasing and reading of the data by the command which is not open to the general user or is disclosed only to specific users, or is not open to any users.

In this embodiment, the memory cells shown by“A” and“B” of the second domain (the non-user area) of FIG. 9 is set to“protection cells” memorizing a“protection flag”. Here, the“protection flag” is used to prohibit writing or erasing of the data. “The writing operation protection flag” is that when the data of a specific protection cell is “0” data, it is recognize that the flag is standing and the writing operation of the entire block is prohibited. “The erasing operation protection flag” is that when the data of a specific protection cell is “0” data, it is recognized that the flag is standing and the erasing operation of the entire block is prohibited. In this embodiment, since the memory cell “A” is set to the writing operation protection flag, when data of the memory cell “A” is “0” data, it is recognized that the flag is standing, and the writing operation of the entire block is prohibited. On the other hand, since the memory cell “B” is set to the erasing operation protection flag, when data of the memory cell “B” is “0” data, it is recognized that the flag is standing, and the erasing operation of the entire block is prohibited.

For information, details regarding the protection flag are described in Japanese patent application 2003-336058 and Japanese laid-open publication 2005-108273, the entire contents of this reference being incorporated herein by reference.

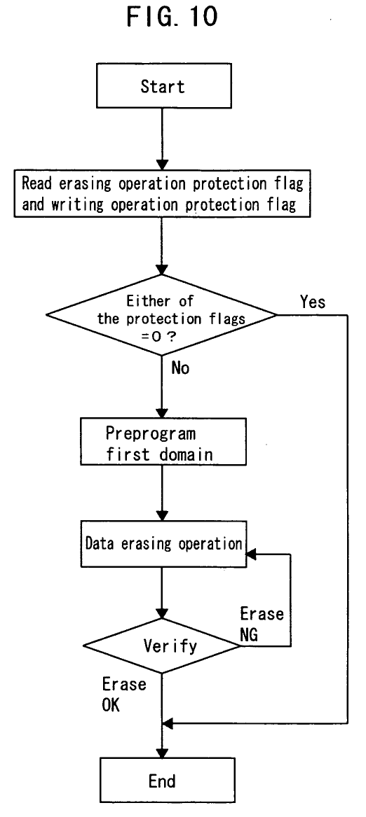

Next, FIG. 10 is referred to. FIG. 10 shows a flowchart at the time of erasing data of a nonvolatile semiconductor memory device concerning this embodiment. Also in this embodiment, the “preprogram” operation explained in the above-mentioned embodiment and FIG. 6 is carried out. In the above-mentioned embodiment, when performing the writing operation before the data erasing operation (the preprogram), threshold voltages of all of the memory cells in the selected block are set to the positive threshold voltages (“0” data). On the other hand, in this embodiment, the preprogram is not carried out to the non-user area (for example, the identification flag area in the NAND) where no user uses (or specific users cannot use) at the time of erasing data, but the data erasing operation is only performed.

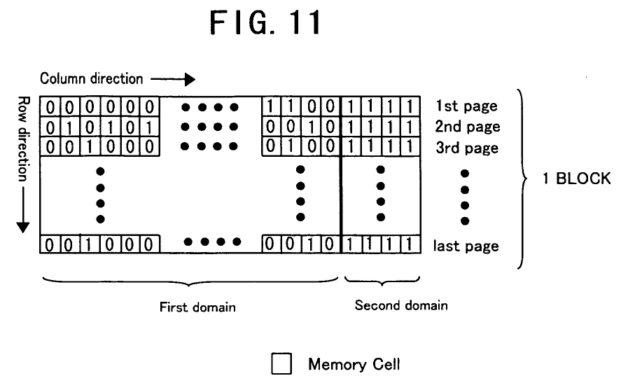

As shown in FIG. 10, at the time of erasing the data of the nonvolatile semiconductor memory device 10 of this embodiment, read-out of the writing operation protection flag and the erasing operation protection flag, namely, read-out of the data of the memory cells “A” and “B” shown in FIG. 9 is performed. When either data of the memory cells “A” or “B” is 0, since the writing protection flag or the erasing operation protection flag is standing, it ends without performing the erasing operation. On the other hand, for example, as shown in FIG. 11, when the data of both of the memory cells “A” and “B” is “1”, since the erasing operation protection flag does not stand and the erasing operation is not prohibited, it moves forward to a next step.

Next, the preprogram of the first domain is performed. By this preprogram, all of the memory cells in the first domain will be the positive threshold voltages (“0” data) Then, the data erasing operation is performed.

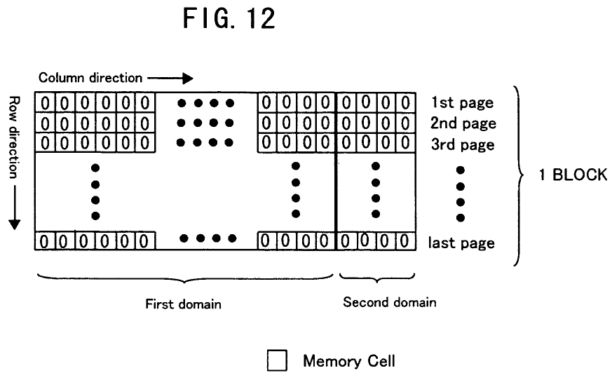

By performing the data erasing operation of the memory cells by such flow, incorrect writing and incorrect erasing of the protection memory cells “A” and “B” of the second domain can be prevented. To be more specific, suppose that preprogram is performed to all of the memory cells in the first and the second domain, after preprogram is finished, if a reset action is carried out before the data erasing operation starts, all of the memory cell data in the block will end with the positive threshold voltages (“0” data). The image diagram of the data in the block at that time is shown in FIG. 12. As shown in FIG. 12, since the writing operation and the erasing operation protection flags become “0” data by performing preprogram to all of the memory cells in the first domain and the second domain, after that, the subject block will fall into the state where the writing operation and the erasing operation are prohibited.

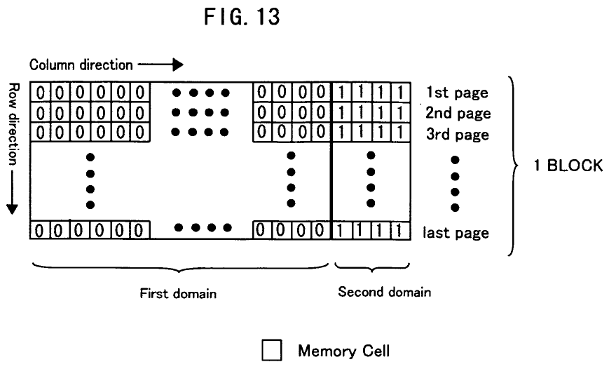

By preprogramming the first domain only without preprogramming the second domain as explained in this embodiment, the data of the second domain remains “1” data (the image diagram of the data in the block at that time is shown in FIG. 13), and after that, the block can be used as usual without prohibiting the writing operation or the erasing operation. Definite operation of the preprogram is that the bit line of the column in the first domain is set to Vss, and after the bit line of the column of the second domain is set to Vcc, the control gate line of the select memory cell in the select NAND cell is set to Vpp (=about 20V: a high voltage for writing) from 0V, and by setting other control gate lines in the select NAND cell to Vmg (=about 10V: a middle voltage) from 0V, preprogram is performed only in the memory cells of the first domain.

FIG. 10 is referred again. After the data erasing operation is performed, verification is carried out whether the data of all memory cells in the selected block are erased completely. When it is verified that the data of all of the memory cells in the selected block are erased completely, erasing of the data is completed. On the other hand, when it is determined that a part of the data of all memory cells in the selected block are not erased, the data erasing operation is performed again. Accordingly, erasing of the data in the selected block is performed.

In the nonvolatile semiconductor memory device concerning this embodiment, by performing preprogram before carrying out the erasing operation to the area other than the area where the identification flag and others are memorized, incorrect erasing of the identification flag is prevented, and threshold voltage distribution after erasing the data can be narrower, and variation of time to complete writing of each memory cell at the time of the writing the data performed continuously after erasing the data can be smaller. In addition, a data-writing defect can be restrained.

### EMBODIMENT 2

In the above-mentioned embodiment 1, two memory cells “A” and “B” in the second domain are set as the writing operation protection flag cell and as the erasing operation protection flag cell, respectively. However, in this embodiment, combination of a plurality of memory cells is set to a protection flag cell. That is, the protection flag is set to stand according to combination of “0” and “1” data of a plurality of the memory cell.

For example, when a data pattern “0101” is memorized using four memory cells in the second domain, the protection flag is set to stand. By setting the protection flag to stand according to the data pattern of at least 2 bits or more, even if a reset action is performed before starting the data erasing operation after the preprogram ends, it can be set that the protection flag is not recognized to stand. The protection flag cell is not limited to 2 bits, and it can be formed depending on the memory cell of a desired bit number.

### EMBODIMENT 3

In the above-mentioned embodiment, Embodiment 1 and Embodiment 2, the NAND cell type nonvolatile semiconductor memory device is used as an example of the nonvolatile semiconductor memory device of one embodiment of the present invention. However, nonvolatile semiconductor memory devices such as a NOR cell type, a DINOR cell type, an AND cell type EEPROM and others can be used as a semiconductor memory device of one embodiment of the present invention.

The nonvolatile semiconductor memory device of one embodiment of the present invention can minimize variation of time to complete writing of each memory cell at the time of writing the data performed continuously after erasing the data. Therefore, according to the present invention, a high-speed nonvolatile semiconductor memory device can be realized. The nonvolatile semiconductor memory device of the present invention can be used as memory storage of electronic equipment including a computer, a digital camera, a cellular phone and home electronics.

What is claimed is:

1. A nonvolatile semiconductor memory device comprising:
memory cell array constituted of a plurality of memory blocks which electrically rewritable memory cells are arranged,
at the time of an erasing operation, before erasing the data of all of said memory cells in memory blocks selected from said plurality of memory blocks, threshold voltages of all of said memory cells in said selected memory blocks are shifted to be positive.

2. A nonvolatile semiconductor memory device according to claim 1, wherein
after shifting all threshold voltages of all of said memory cells in said selected memory blocks positive at the time of said erasing operation,
the data of all of said memory cells in said selected memory blocks are erased,
after that, it is verified whether the data of all of said memory cells in said selected memory blocks are erased,
when the data of all of said memory cells in said selected memory blocks are not erased,
the data of all of said memory cells in said selected memory blocks are erased again.

3. A nonvolatile semiconductor memory device according to claim 1, wherein said memory cell block comprises a plurality of memory cell unit which said plurality of memory cells are connected between the two selection gates.

4. A nonvolatile semiconductor memory device according to claim 3, wherein said memory cell has a structure which an electric charge accumulation layer and a control gate are laminated.

5. A nonvolatile semiconductor memory device comprising: memory cell array constituted of a plurality of memory blocks which an electrically rewritable memory cells are arranged,
said plurality of memory blocks are composed of the first domain and the second domain respectively,
when the data of a specific memory cell of said memory cells in said second domain of a memory block selected from said plurality of memory blocks is the first value,
writing or erasing of the data to said selected memory blocks is permitted,
when the data of said specific memory cell is the second value,
writing or erasing of the data to said selected memory blocks is prohibited,
when writing or erasing of the data to said memory blocks is permitted,
before erasing the data of all of said memory cells in said selected memory blocks at the time of the erasing operation,
all threshold voltages of all of said memory cells of said first domain in said selected memory block are shifted to be positive.

6. A nonvolatile semiconductor memory device according to claim 2, wherein said specific memory cells are a plurality of memory cells.

7. A nonvolatile semiconductor memory device according to claim 5, wherein commands for writing, erasing or reading of data of memory cells in said first domain and of memory cells in said second domain differ respectively.

8. A nonvolatile semiconductor memory device according to claim 5, wherein
after shifting all threshold voltages of all of said memory cells in said selected memory blocks to positive at the time of said erasing operation,
data of all of said memory cells in said selected memory blocks are erased,
then, it is verified whether the data of all of said memory cells in said selected memory blocks are erased,
when the data of all of said memory cells in said selected memory blocks are not erased,
the data of all of said memory cells in said selected memory blocks are erased again.

9. A nonvolatile semiconductor memory device according to claim 5, wherein said memory cell block comprises a plurality of memory cell units which said plurality of memory cells are connected between two selection gates.

10. A nonvolatile semiconductor memory device according to claim 9, wherein said memory cells have a structure which an electric charge accumulation layer and a control gate are laminated.

11. A method of erasing data of a nonvolatile semiconductor memory device comprising:
memory cell array constituted of a plurality of memory blocks which electrically rewritable memory cells are arranged,
before erasing the data of all of said memory cells in memory blocks selected from said plurality of memory blocks at the time of erasing operation,
all threshold voltages of all of said memory cells in said selected memory blocks are shifted to be positive.

12. A method of erasing data of a nonvolatile semiconductor memory device according to claim 11, wherein
after changing all threshold voltages of all of said memory cells in said selected memory blocks to positive at the time of said erasing operation,
the data of all of said memory cells in said selected memory blocks are erased,
after that, it is verified whether the data of all of said memory cells in said selected memory blocks are erased,
when the data of all of said memory cells in said selected memory block are not erased,
the data of all of said memory cells in said selected memory blocks are erased again.

13. A method of erasing data of a nonvolatile semiconductor memory device according to claim 11, wherein said memory cell blocks comprise a plurality of memory cell units which said plurality of memory cells are connected between two selection gates.

14. A method of erasing data of a nonvolatile semiconductor memory device according to claim 13, wherein said memory cells comprise a structure which an electric charge accumulation layer and a control gate are laminated.

15. A method of erasing data of a nonvolatile semiconductor memory device comprising:
memory cell array constituted of a plurality of memory blocks which an electrically rewritable memory cells are arranged,
said plurality of memory blocks are composed of the first domain and the second domain respectively,
when the data of a specific memory cell of said memory cells in said second domain of a memory block selected from said plurality of memory blocks is the first value,
writing or erasing of the data to said selected memory blocks is permitted,
when the data of said specific memory cell is the second value,
writing or erasing of the data to said selected memory blocks is prohibited,
when writing or erasing of the data to said memory blocks is permitted,
before erasing the data of all of said memory cells in said selected memory blocks at the time of the erasing operation,
all threshold voltages of all of said memory cells of said first domain in said selected memory block are shifted to be positive.

16. A method of erasing data of a nonvolatile semiconductor memory device according to claim 15, wherein said specific memory cells are a plurality of memory cells.

17. A method of erasing data of a nonvolatile semiconductor memory device according to claim 15, wherein commands for writing, erasing or reading of the data of memory cells in said first domain and of memory cells in said second domain differ respectively.

18. A method of erasing data of a nonvolatile semiconductor memory device according to claim 15, wherein after changing all threshold voltages of all of said memory cells in said selected memory blocks to positive at the time of said erasing operation,
the data of all of said memory cells in said selected memory blocks are erased,
then, it is verified whether the data of all of said memory cells in said selected memory blocks are erased,
when the data of all of said memory cells in said selected memory blocks are not erased,
the data of all of said memory cells in said selected memory blocks are erased again.

19. A method of erasing data of a nonvolatile semiconductor memory device according to claim 15, wherein said memory cell block comprises a plurality of memory cell units which said plurality of memory cells are connected between two selection gates.

20. A method of erasing data of a nonvolatile semiconductor memory device according to claim 19, wherein said memory cells have a structure which an electric charge accumulation layer and a control gate are laminated.
